(19) United States
(12) Patent Application Publication
(10) Pub. No.: US 2010/0207676 A1
(43) Pub. Date: Aug. 19, 2010

(54) SIGNAL CONVERTING DEVICE

(76) Inventors: Jeng-Tzong Shih, Hsin Chu City (TW); Chun Shiah, Hsinchu City (TW); Ho-Yin Chen, Hsin Chu County (TW)

Correspondence Address: Muncy, Geissler, Olds & Lowe, PLLC, 4000 Legato Road, Suite 310, FAIRFAX, VA, 22033, US

(21) Appl. No.: 12/703,985

(22) Filed: Feb. 11, 2010

(30) Foreign Application Priority Data
Feb. 18, 2009 (TW) 098105058

(51) Int. Cl. H03K 5/00; H03L 5/00

(52) U.S. Cl. 327/178; 327/306

(57) ABSTRACT

The invention discloses a signal converting device, and more particularly, to a signal converting device that improves the signal quality. The signal converting device comprises a first input end, a second input end, an output end, a first circuit and a second circuit. The first circuit is coupled between the first input end and the output end. The first circuit determines whether to charge up the output end to generate an output signal or not according to a first differential input signal. The second circuit is coupled between the second input end and the output end. The second circuit determines whether to discharge the output end to generate the output signal or not according to a second differential input signal.

### BACKGROUND OF THE INVENTION

(a) Field of the Invention

The present invention relates to a signal converting device and more particularly to a signal converting device that improves the signal quality.

(b) Description of the Related Art

As shown in FIG. 1A, generally a comparator is used to convert the differential signals Sa, Sb into the single-ended signal So in a circuit according to the prior art. But, due to the RC-delay effect that usually exists in the transmission circuitries for the differential signals, the transitions of the signals Sa, Sb from high to low (falling edge) or from low to high (rising edge) usually bear a bad slope as indicated by the portions “up” and “dn” shown in FIG. 1A. As shown in FIG. 1B, in the differential signal, the rising edge “up” of the signal Sa has a center point T1 and the falling edge “dn” of the signal Sb has a center point T2. The points T1 and T2 are at different timing point. Thus, the signal skew occurs so that the signal quality of the output signal So becomes deteriorated.

### BRIEF SUMMARY OF THE INVENTION

One object of the invention is to provide a signal converting device that improves the signal quality.

According to one embodiment of the invention, a signal converting device is provided. The signal converting device, which has a first input end, a second input end, and an output end, comprises a first circuit and a second circuit. The first circuit is coupled between the first input end and the output end. The first circuit determines whether to charge the output end to generate an output signal or not according to a first input signal received by the first input end. The second circuit is coupled between the second input end and the output end. The second circuit determines whether to discharge the output end to generate the output signal according to a second input signal received by the second input end. The above-mentioned first input signal and the second input signal are differential signals. The first circuit and the second circuit determine the transition of the voltage level of the output signal according to the same waveform positions of the transitions of the first input signal and the second input signal.

According to another embodiment of the invention, a signal converting device is provided. The signal converting device comprises a receiving end and a conversion circuit. The receiving end receives a set of differential signals. The set of differential signals comprises a first input signal and a second input signal. The conversion circuit is coupled to the receiving end for generating an output signal according to a first waveform transition of the first input signal and a first waveform transition of the second input signal. The output signal changing from a first transient voltage to a second transient voltage is determined by the first waveform transition of the first input signal. The output signal changing from the second transient voltage to the first transient voltage is determined by the first waveform transition of the second input signal.

The signal converting device according to the embodiments of the invention can control the single-ended output signal simply via the rising edge or the falling edge of the differential signal so as to improve the signal quality.

### BRIEF DESCRIPTION OF THE DRAWINGS

FIG. 1A shows a schematic diagram illustrating a signal converting device according to the prior art.

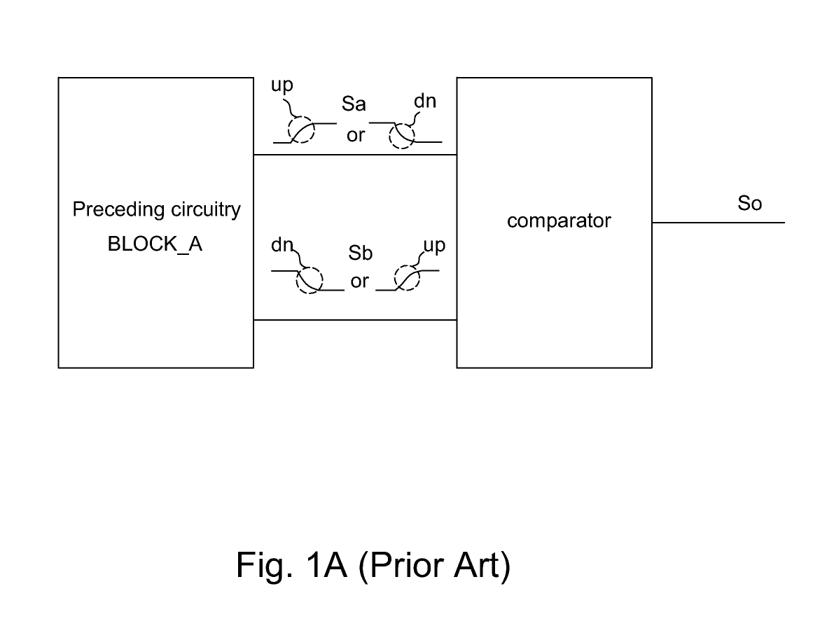

FIG. 1B shows a schematic diagram illustrating the waveforms of the output voltage during the operation of the signal converting device shown in FIG. 1A operates.

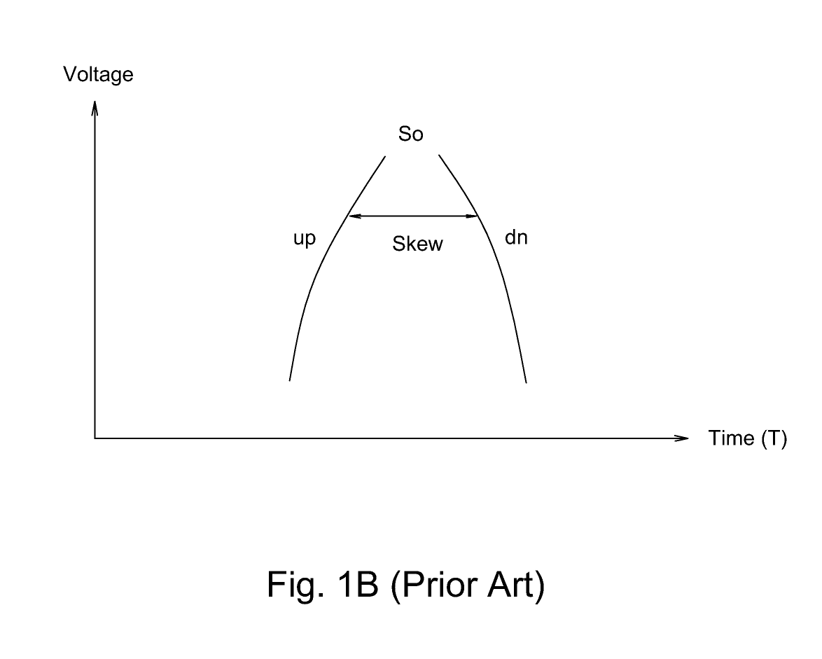

FIG. 2A shows a schematic diagram illustrating the signal converting device according to one embodiment of the invention.

FIG. 2B shows a schematic diagram illustrating the waveforms of the input signal and the output signal shown in FIG. 2A.

FIG. 2C shows a schematic diagram illustrating another waveforms of the input signal and the output signal shown in FIG. 2A.

FIG. 3A shows a schematic diagram illustrating the signal converting device according to another embodiment of the invention.

FIG. 3B shows a schematic diagram illustrating the waveforms of the input signal and the output signal shown in FIG. 3A.

### DETAILED DESCRIPTION OF THE INVENTION

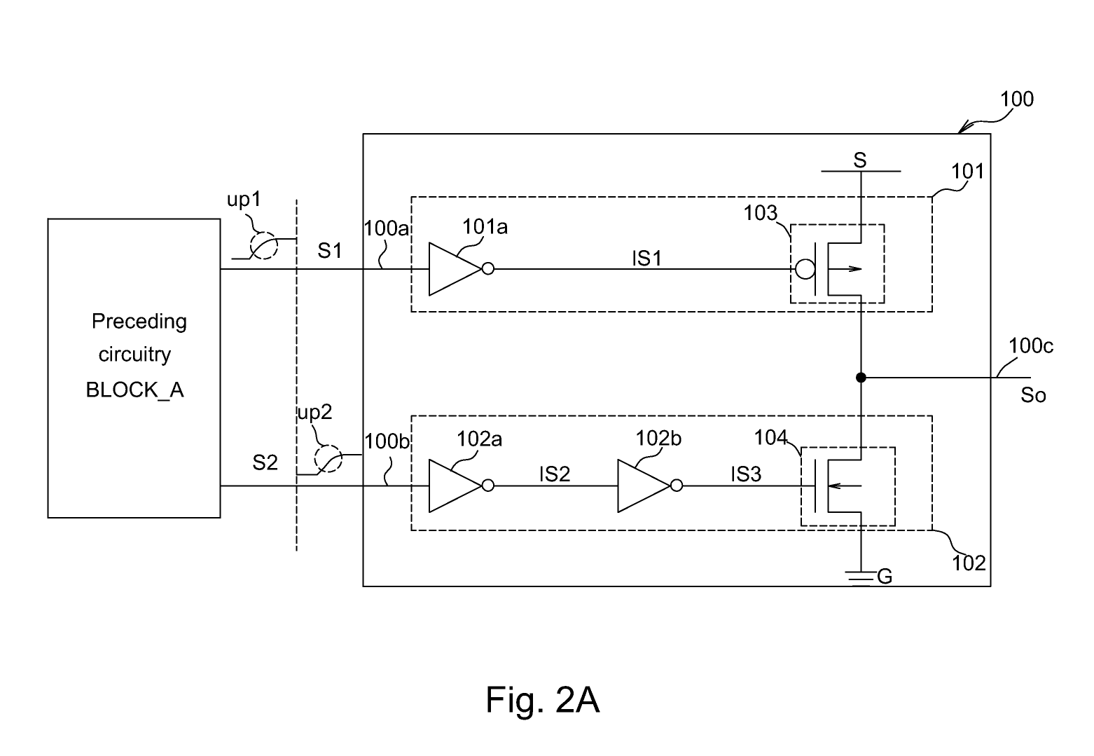

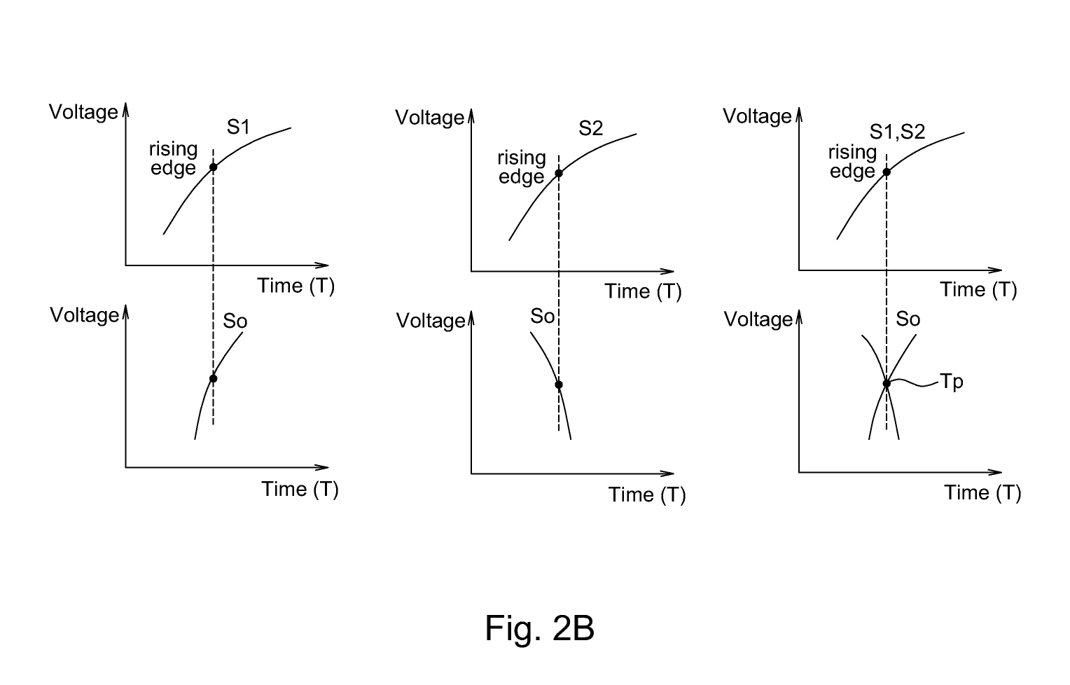

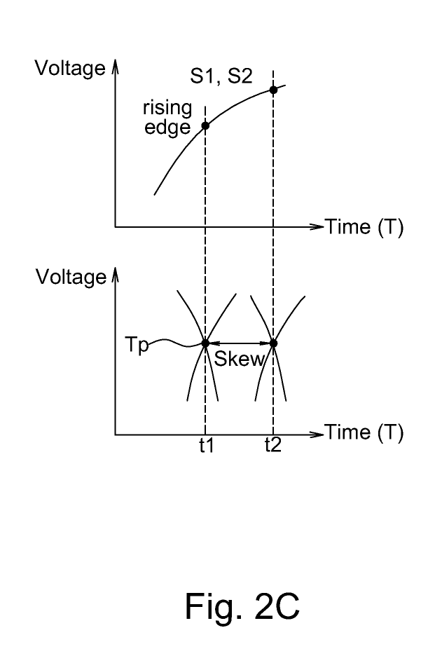

FIG. 2A shows a schematic diagram illustrating the signal converting device according to one embodiment of the invention. The signal converting device 100 comprises a first circuit 101 and a second circuit 102 for converting the differential signal into the single-ended signal. The I/O (input/output) portion of the signal converting device 100 comprises a first input end 100a, a second input end 100b, and an output end 100c.

The first circuit 101 is coupled between the first input end 100a and the output end 100c. The first circuit 101 determines whether to charge the output end 100c to generate an output signal So or not according to a first input signal S1 received by the first input end 100a. The first circuit 101 comprises an inverter 101a and a first switch 103. In one embodiment, the first switch 103 is a PMOS transistor.

The second circuit 102 is coupled between the second input end 100b and the output end 100c. The second circuit 102 determines whether to discharge the output end 100c to generate the output signal So or not according to a second input signal S2 received by the second input end 100b. The second circuit 102 comprises two inverters 102a, 102b and a second switch 104. In one embodiment, the second switch 104 is an NMOS transistor.

The above-mentioned first input signal S1 and the above-mentioned second input signal S2 are differential signals. The first circuit 101 and the second circuit 102 determine the transition of the voltage level of the output signal So according to the same waveform positions of the transitions of the first input signal S1 and the second input signal S2. The waveform positions of the transitions of the first input signal S1 and the second input signal S2 can both be at the rising edges of the input signals.

In one embodiment, the above-mentioned inverters 101a, 102a can be implemented by the inverters having substantially the same characteristics. For example, the inverter 101a and 102a can be implemented by exactly the same circuit layout so that the voltage transitions occur at the same position. The number of inverters in the first circuit 101 or the second circuit 102 is not limited to this example. The number of inverters provided in the two circuits can be adjusted according to the design. For example, the first circuit 101 can comprise three inverters while the second circuit 102 can comprise four inverters.

In this embodiment, the inverter 101a is coupled to the first input end 100a to receive the first input signal S1 and convert the phase of the first input signal S1 for outputting a first inverting signal IS1. The inverter 102a is coupled to the second input end 100b to convert the phase of the second input signal S2 for outputting a second inverting signal IS2 to the inverter 102b. The phase of the second inverting signal is then converted by the inverter 102b for outputting a third inverting signal IS3. The above-mentioned first input signal S1 and the above-mentioned second input signal S2 are differential signals.

In this embodiment, the gate terminal of the PMOS transistor of the first switch 103 is coupled to the inverter 101a and the gate terminal of the NMOS transistor of the second switch 104 is coupled to the inverter 102b. The source terminal of the transistor 103 is coupled to a power supply S and the source of the transistor 104 is coupled to the ground G. The drain terminals of the transistors 103, 104 and the output end 100c are mutually coupled together.

In order to illustrate the operating principle of the signal converting device 100 according to one embodiment of the invention, referring to FIGS. 2A, 2B and 2C simultaneously, the signal converting device 100 uses the rising edges of the differential signals S1, S2 as the basis of control.

When the preceding circuitry BLOCK-A outputs the first input signal S1 and the second input signal S2, the signal converting device 100 receives the two differential signals S1 and S2 and the first circuit 101 receives the differential signal S1. When the differential signal S1 transitions from logic 0 to logic 1, the inverter 101a generates a first inverting signal IS1 transitioning from logic 1 to logic 0 to drive and turn on (On) the first switch 103 for charging the output end 100c. As shown on the left-hand side of the FIG. 2B, as the voltage level of the rising edge “up1” of the differential signal S1 becomes higher, the voltage level of the output signal So is raised so that the output signal So transitions from logic 0 to logic 1. Whereas the differential signal S2 transitions from logic 1 to logic 0 and, after passing through the two inverters 102a, 102b, the third inverting signal IS3 remains at logic 0 so that the second switch 104 is turned off (Off). Therefore, the transition of the differential signal S2 from logic 1 to logic 0 does not influence the output signal So.

On the other hand, as the differential signal S1 transitions from logic 1 to logic 0, the first inverting signal IS1 is at logic 1 after passing through the inverter 101a and then the first switch 103 is turned off (Off). Therefore, the transition of the differential signal S1 from logic 1 to logic 0 does not influence the output signal So. Referring to the middle of FIG. 2B, as the differential signal S2 transitions from logic 0 to logic 1, after passing through the two inverters 102a, 102b, the third inverting signal IS3 is at logic 1 to turn on the second switch 104 (On) for discharging the output end 100c. The voltage level of the output signal So is gradually decreased so that the output signal So transitions from logic 1 to logic 0.

The signal converting device 100 according to the embodiment of the invention controls the differential signal by using the rising edges of the two differential signals S1, S2 to generate the waveform of the output signal shown in the figures. As shown in the graph on the right-hand side of FIG. 2B, it is the result of overlapping the graph on the left-hand side with the graph in the middle of the FIG. 2B. As shown in the graph on the right-hand side, the slopes of the rising edges of the two differential signals S1, S2 are similar. Thus, the voltage of the crossing point Tp between the transition curve P1 of the output signal So transitioning from logic 0 to logic 1 and the transition curve P2 of the output signal So transitioning from logic 1 to logic 0 is close to (V_{H}+V_{L})/2. Therefore the output signal So has better signal quality.

Furthermore, when the rising edge of the differential signals S1, S2 deteriorates from the better slope Q1 to the poorer slope Q2 as shown in FIG. 2C due to environmental factors, such as the RC delay effect of the preceding circuitry BLOCK-A and the transmission circuitries or other processes or the like, the crossing point Tp between the voltage transition curves P1 and P2 of the output voltage So is drifted. But, the drifting patterns and positions are still properly controlled by the signal converting device 100 so that the voltage of the drifted crossing point Tp is still close to the (V_{H}+V_{L})/2. Therefore, the signal quality of the output signal So is maintained.

Therefore, the signal converting device 100 according to the embodiment of the invention controls the differential signal by using the two rising edges of the differential signals S1, S2 to generate the output signal So for solving the problem of the errors generated by the signal drifting in the prior art.

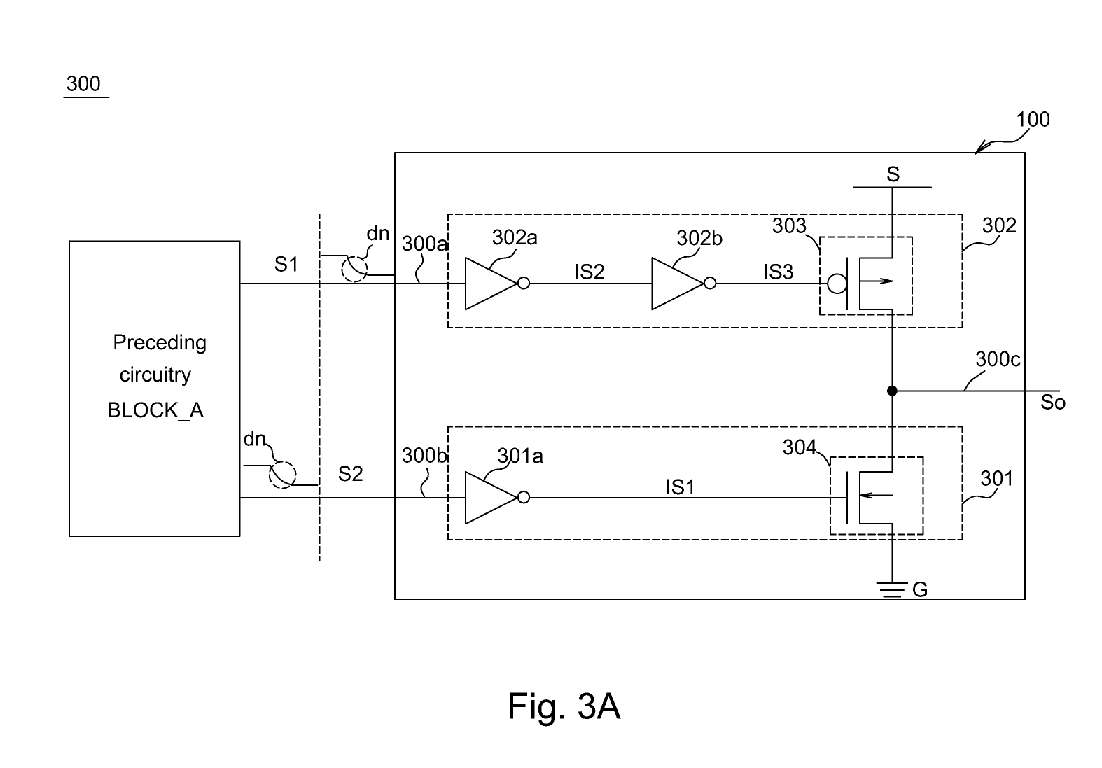

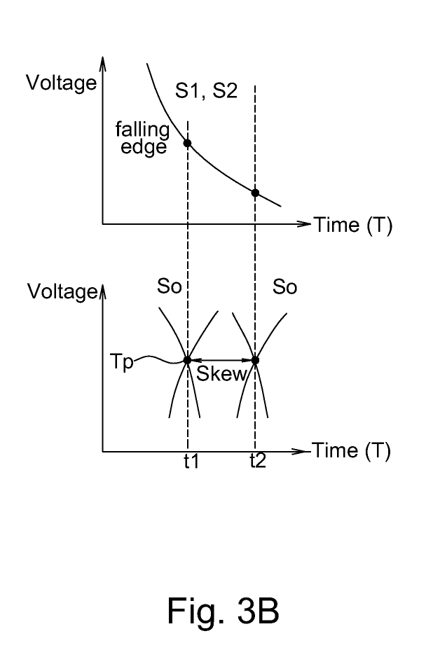

The signal converting device according to the embodiment of the invention can also controls the differential signal by using the falling edges of the two differential signals S1, S2 to generate the output signal. As shown in FIG. 3A, the signal converting device 300 according to one embodiment of the invention comprises a first circuit 301 and a second circuit 302. The I/O (input/output) portion of the signal converting device 300 comprises a first input end 300a, a second input end 300b, and an output end 300c. The first circuit 301 comprises an inverter 301a and a first switch 303. The second circuit 302 comprises two inverters 302a, 302b and a second switch 304. It should be noted, since the architecture and the functions of the various components of the signal converting device 300 are approximately the same as those of the signal converting device 100, further details will not be given herein.

According to the embodiment of the invention, as the differential signal S1 transitions from logic 1 to logic 0, after passing through the two inverters 302a, 302b, the switch 303 is turned on (On) and the voltage level of the output signal So is gradually increased so that the output signal So transitions from logic 0 to logic 1. While at the same time the differential signal S2 transitions from logic 0 to logic 1, after passing through the inverter 301a, the switch 304 is turned off (Off). Therefore, the transition of the differential signal S2 from logic 0 to logic 1 does not influence the output signal So. On the other hand, as the differential signal S2 transitions from logic 1 to logic 0, after passing through the inverter 301a, the switch 304 is tuned on (On) and the voltage level of the output signal So transitions from logic 1 to logic 0. While at the same time the differential signal S1 transitions from logic 0 to logic 1, after passing through the inverters 302a, 302b, the switch 303 is turned off (Off). Therefore, the transition of the differential signal S1 from logic 0 to logic 1 does not influence the output signal So.

In this embodiment, if the voltage levels for the state transition in the inverters 302a, 302b are changed due to the process variations, the voltage transition of So, that is supposed to occur at the point R1 where the differential signals S1, S2 are at the falling edges, occurs at the point R2, as shown in FIG. 3B. Thus, the crossing point Tp between the voltage transition curves P1 and P2 of the output voltage So is drifted. However, the drifting patterns and positions are still properly controlled by the signal converting device 100 so that the voltage of the drifted crossing point Tp is still close to (V_{H}+V_{L})/2. Therefore, the signal quality of the output signal So is maintained.

In conclusion, the signal converting devices according to embodiments of the invention can control the single-ended output signal simply via the rising edge or the falling edge of the differential signal to achieve the effect of improving the signal quality.

Although the present invention has been fully described by way of preferred embodiments of the invention with reference to the accompanying drawings, various equivalent changes and modifications of the shape, scope, characteristics, and spirit as described by the claims of the present invention is to be encompassed by the scope of the present invention.

What is claimed is:

1. A signal converting device having a first input end, a second input end, and an output end, the signal converting device comprising:
a first circuit coupled between the first input end and the output end for determining whether to charge the output end to generate an output signal or not according to a first input signal received by the first input end; and
a second circuit coupled between the second input end and the output end for determining whether to discharge the output end to generate the output signal or not according to a second input signal received by the second input end;
wherein the first input signal and the second input signal are differential signals; and the first circuit and the second circuit determine the voltage level transition of the output signal according to the same waveform transition positions of the first input signal and the second input signal.

2. The signal converting device according to claim 1, wherein the voltage level transition of the output signal is determined according to the rising edges of the waveform transitions of the first input signal and the second input signal.

3. The signal converting device according to claim 1, wherein the voltage level transition of the output signal is determined according to the falling edges of the waveform transitions of the first input signal and the second input signal.

4. The signal converting device according to claim 1, wherein the first circuit comprises:
a first inverter for inverting the phase of the first input signal to output a first invert signal; and
a first switch coupled to the first inverter for determining whether to charge the output end or not according to the first invert signal.

5. The signal converting device according to claim 4, wherein the second circuit comprises:
a second inverter for inverting the phase of the second input signal to output a second invert signal;
a third inverter for inverting the phase of the second invert signal to output a third invert signal; and
a second switch coupled to the third inverter for determining whether to discharge the output end or not according to the third invert signal.

6. The signal converting device according to claim 5, wherein the first switch is a PMOS transistor and the second switch is a NMOS transistor.

7. The signal converting device according to claim 5, wherein the characteristics of the first inverter and the second inverter are substantially the same.

8. A signal converting device, the signal converting device comprising:
a receiving end for receiving a set of differential signals comprising a first input signal and a second input signal; and
a conversion circuit coupled to the receiving end for generating an output signal according to a first waveform transition of the first input signal and a first waveform transition of the second input signal;
wherein the output signal changing from a first transient voltage to a second transient voltage is determined by the first waveform transition of the first input signal and the output signal changing from the second transient voltage to the first transient voltage is determined by the first waveform transition of the second input signal.

9. The signal converting device according to claim 8, wherein the first waveform transition is a rising edge.

10. The signal converting device according to claim 8, wherein the first waveform transition is a falling edge.

11. The signal converting device according to claim 8, wherein the conversion circuit comprises:
a first circuit coupled to the receiving end for changing the output signal from the first transient voltage to the second transient voltage according to the first waveform transition of the first input signal; and
a second circuit coupled to the receiving end for changing the output signal from the second transient voltage to the first transient voltage according to the first waveform transition of the second input signal.

12. The signal converting device according to claim 11, wherein the first circuit comprises a first switch and the first switch is switched off when the first circuit receives a second waveform transition of the first input signal.

13. The signal converting device according to claim 12, wherein the first waveform transition is a rising edge and the second waveform transition is a falling edge.

14. The signal converting device according to claim 11, wherein the second circuit comprises a second switch and the second switch is switched off when the second circuit receives a second waveform transition of the second input signal.

15. The signal converting device according to claim 14, wherein the first waveform transition is a falling edge and the second waveform transition is a rising edge.
